(19) United States
(12) Patent Application Publication
(10) Pub. No.: US 2009/0306916 A1
(43) Pub. Date: Dec. 10, 2009

(54) ELECTRICAL CHARACTERISTIC ANALYZING APPARATUS FOR SUBSTANCE ON WHICH METAL-CONTAINING PAINT IS COATED

(75) Inventor: Kenji Nagase, Kawasaki (JP)

Correspondence Address: GREER, BURNS & CRAIN, 300 S WACKER DR, 25TH FLOOR, CHICAGO, IL, 60606, US

(73) Assignee: FUJITSU LIMITED, Kawasaki-shi (JP)

(21) Appl. No.: 12/544,683

(22) Filed: Aug. 20, 2009

Related U.S. Application Data
(63) Continuation of application No. PCT/JP2008/000364, filed on Feb. 27, 2008.

(30) Foreign Application Priority Data
Feb. 28, 2007 (JP) 2007-048949

(51) Int. Cl. G06F 19/00; G01R 27/00

(52) U.S. Cl. 702/65

(57) ABSTRACT

To provide an electrical characteristic analyzing apparatus that can analyze the electrical characteristic of a substance, on which a paint containing a metal is coated, with ease and in a short time, the electrical characteristic analyzing apparatus comprises an analysis model obtaining unit for obtaining analysis model information, a wave source information obtaining unit for obtaining wave source information, a property value obtaining unit for obtaining property values of an analysis model, and an electromagnetic field analyzing unit for analyzing an electrical characteristic at an observation point according to an electric or magnetic signal provided from a wave source.

### CROSS-REFERENCE TO RELATED APPLICATION

This application is a continuation of PCT application of PCT/JP2008/000364, which was filed on Feb. 27, 2008.

### FIELD

The present invention relates to an apparatus for analyzing an electrical characteristic of a substance on which a paint containing a metal is coated.

### BACKGROUND

In recent years, the number of cases where a so-called touch panel is used as an operation unit (such as a replay button) of a music player, etc. has been increasing. The touch panel detects an operation by attaching an electrostatic sensor to the operation unit made of, for example, plastic, and by detecting that a capacitive component between a finger and the sensor changes when the finger is brought close to the operation unit.

In the meantime, a so-called metallic paint containing a metal is sometimes coated on a body of the music player, etc. because of its good looks. The metallic paint is also coated on the touch panel. If the quantity of a metal contained in the metallic paint is large, the capacitance between the finger and the sensor increases, leading to a decrease in a change of the capacitive component. As a result, the sensor does not work. Therefore, it is necessary to analyze the content of the metal that enables the sensor to properly work.

Related to the above described technique, Japanese Published Unexamined Patent Application No. 2002-180295 discloses the electrodeposition painting analysis method that improves the accuracy of an electrodeposition painting analysis by adding also a physical amount in addition to a current density when the amount of a coating deposition is obtained from the current density of the surface of a paint-coated object, which is acquired with a potential analysis. Additionally, Japanese Published Unexamined Patent Application No. 2002-327294 discloses the electrodeposition coating thickness calculating method that can calculate the thickness of coating deposited on each part of a paint-coated object with high accuracy by using an analysis model that replaces the paint-coated object.

Here, if the content of a metal that can enable the sensor to properly work is analyzed with an FDTD (Finite Difference Time Domain) method, or the like, a time step (the minimum unit of time for a simulation) is determined according to the thickness of a metallic paint coated on the body.

Normally, since the thickness of a metallic paint coated on the body is on the order of several μm to nm or less, the time step must be decreased according to the thickness. This poses a problem such that analysis results cannot be obtained with a simulation in realistic time.

### SUMMARY

The present invention was developed in view of the above described problems, and an object thereof is to provide an electrical characteristic analyzing apparatus that can analyze the electrical characteristic of a substance, on which a paint containing a metal is coated, with ease and in a short time.

To overcome the above described problems, the electrical characteristic analyzing apparatus according to the present invention, which analyzes an electrical characteristic at an observation point according to an electric or magnetic signal provided from a wave source for a substance on which a paint containing a metal at a predetermined ratio is coated, comprises an analysis model obtaining unit for reading from a storing unit analysis model information that defines a domain to be analyzed, which includes the substance on which the paint is coated, a wave source information obtaining unit for reading from the storing unit signal information provided from the wave source, a property value obtaining unit for reading from the storing unit property values of the substance within the domain to be analyzed, which include a conductivity of the paint, and an electromagnetic field analyzing unit for obtaining a change in electric and magnetic fields at the observation point according to the electric or magnetic signal provided from the wave source by analytically calculating electric and magnetic fields of each of meshes, into which the domain to be analyzed is partitioned, based on Maxwell's equations.

According to the present invention, the property value obtaining unit obtains the conductivity of the paint. Therefore, the electromagnetic field analyzing unit can analytically calculate a paint containing a metal at a predetermined ratio as a dielectric having a conductivity. Therefore, the paint can be simply put into a model. As a result, the electrical characteristic at the observation point according to the electric or magnetic signal provided from the wave source can be analyzed with ease and in a short time for the substance on which the paint containing the metal at the predetermined ratio is coated.

As described above, the present invention can provide an electrical characteristic analyzing apparatus that can analyze the electrical characteristic of a substance, on which a paint containing a metal is coated, with ease and in a short time.

### BRIEF DESCRIPTION OF DRAWINGS

FIG. 1 is a schematic diagram explaining the principle of operations of an electrical characteristic analyzing apparatus according to a preferred embodiment of the present invention;

FIG. 2 is a block diagram exemplifying a configuration of the electrical characteristic analyzing apparatus according to the preferred embodiment of the present invention;

FIG. 3 is a perspective view of an analysis model analyzed by the electrical characteristic analyzing apparatus according to the preferred embodiment of the present invention;

FIG. 4 is a circuit diagram showing an equivalent circuit of the analysis model according to the preferred embodiment of the present invention;

FIG. 5 is a cross-sectional view when the analysis model according to the preferred embodiment of the present invention is partitioned into meshes;

FIG. 6 is an enlarged view of meshes into which the analysis model according to the preferred embodiment of the present invention is partitioned;

FIG. 7 is a flowchart showing a specific process of the electrical characteristic analyzing apparatus according to the preferred embodiment of the present invention; and

FIGS. 8A, 8B, and 8C are waveform diagrams showing signals at a wave source and an observation point of the analysis model according to the preferred embodiment of the present invention.

### DESCRIPTION OF EMBODIMENTS

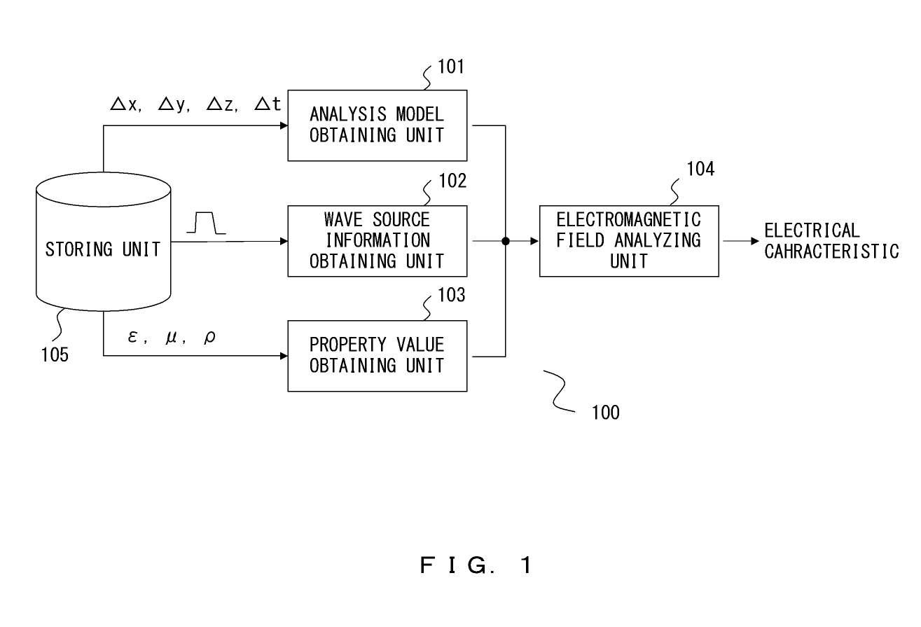

A preferred embodiment according to the present invention is described below with reference to FIGS. 1 to 8.

FIG. 1 is a schematic diagram explaining the principle of operations of an electrical characteristic analyzing apparatus 100 according to the preferred embodiment of the present invention.

The electrical characteristic analyzing apparatus 100 shown in FIG. 1 comprises an analysis model obtaining unit 101 for obtaining analysis model information, a wave source information obtaining unit 102 for obtaining wave source information, a property value obtaining unit 103 for obtaining property values of an analysis model, and an electromagnetic field analyzing unit 104 for analyzing an electrical characteristic at an observation point according to an electric or magnetic signal provided from a wave source.

The analysis model obtaining unit 101, the wave source information obtaining unit 102 and the property value obtaining unit 103 read the analysis model information, the wave source information and the property values respectively from predetermined positions of a storing unit 105.

Here, the analysis model information includes at least the shapes of a paint (hereinafter referred to simply as a metallic paint) containing a metal at a predetermined ratio and a substance on which the metallic paint is coated, a domain (space) to be analyzed, which includes the substance, the size of meshes into which the domain is partitioned, and a time step of an analysis time.

The wave source information is information about the electric or magnetic signal provided to the analysis model at the wave source. For example, an electric signal, an electromagnetic wave or the like may be provided.

The property values include at least a permittivity ε, a permeability μ, and a conductivity ρ of a substance, for example, in a domain (space) to be analyzed. Here, the property values according to this preferred embodiment are assumed to always include the conductivity of a metallic paint. Namely, in the electromagnetic field analyzing unit 104, the metallic paint according to this preferred embodiment is analytically calculated as a dielectric having a predetermined conductivity.

When the above described information are obtained, the electromagnetic field analyzing unit 104 obtains a change in the electric and the magnetic fields at an observation point according to an electric or magnetic signal provided from the wave source by analytically calculating the electric and the magnetic fields of each of meshes, into which the domain to be analyzed is partitioned, based on Maxwell's equations. Then, an electrical characteristic at a desired observation point is obtained, for example, from a relationship between the electric field and a potential.

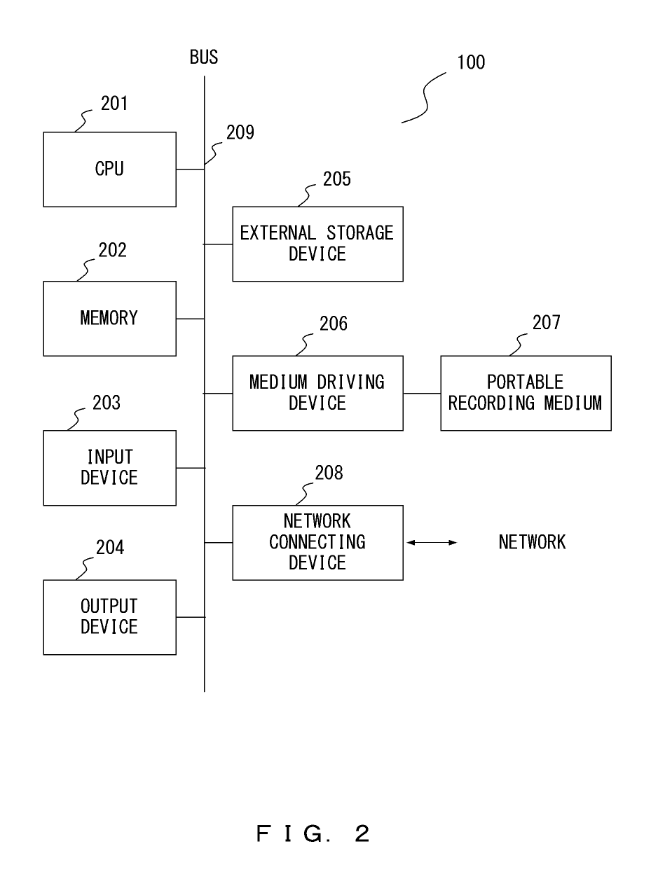

FIG. 2 is a block diagram exemplifying a configuration of the electrical characteristic analyzing apparatus 100 according to the preferred embodiment of the present invention.

The electrical characteristic analyzing apparatus 100 shown in FIG. 2 comprises a CPU 201 that executes a program for implementing an electrical characteristic analysis according to this preferred embodiment, a volatile memory 202 (such as a RAM) used to execute the program, an input device 203 (such as a keyboard or a mouse), which is an input unit of data, etc. to the electrical characteristic analyzing apparatus 100, an output device 204 for outputting data, etc. to a display device, an external storage device 205 for recording a program and data, which are required to implement the electrical characteristic analyzing apparatus 100, a medium driving device 206 for outputting the data of the memory 202 or the external storage device 205 to a portable recording medium 207 (such as a floppy disk, an MO disk, a CD-R, a DVD-R, etc.) and for reading the program, the data, etc. from the portable recording medium 207, and a network connecting device 208 for making a connection to a network. These constituent elements are interconnected by a bus 209, and can mutually transmit/receive data.

The input device 203, the output device 204, the external storage device 205, the medium driving device 206, and the network connecting device 208 are not always required, and may be comprised as needed.

In the above described configuration, the analysis model obtaining unit 101, the wave source information obtaining unit 102, the property value obtaining unit 103, and the electromagnetic field analyzing unit 104 are implemented by causing the CPU 210 to execute instructions written in a predetermined program.

The electrical characteristic analysis made by the electrical characteristic analyzing apparatus 100 according to this preferred embodiment is described below.

### Analysis Model

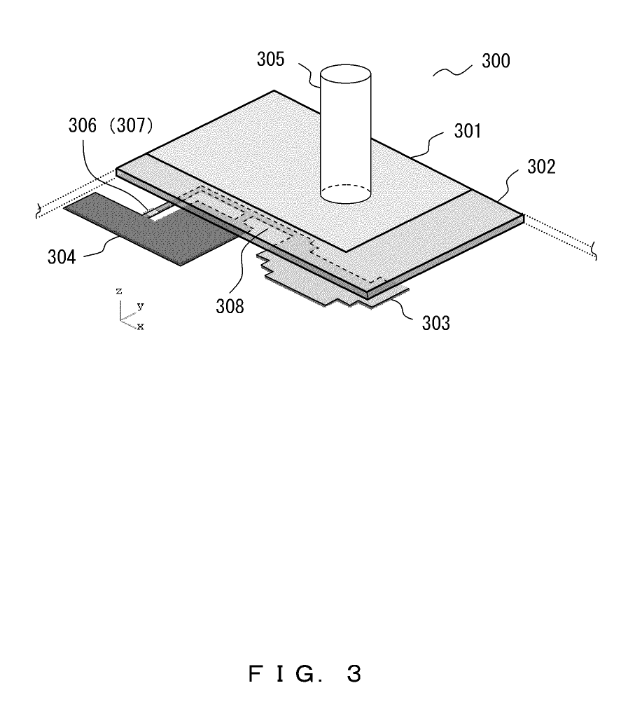

FIG. 3 is a perspective view of an analysis model analyzed by the electrical characteristic analyzing apparatus 100 according to this preferred embodiment.

The analysis model 300 shown in FIG. 3 is structured by stacking, as layers, a metallic paint 301 that contains a metal at a predetermined ratio, a body 302 of a music player, etc., a planar capacitive sensor 303, and an ASIC 304 of a ground layer. The planer capacitive sensor 303 and the ASIC 304 are connected with a wiring pattern 308.

In this preferred embodiment, the metallic paint 301 is handled as a dielectric having a predetermined conductivity without putting the metallic paint 301 into a specific model (for example, without defining the metallic paint 301 as a dielectric where metal particles are uniformly scattered at a predetermined ratio).

The body 302 is assumed to be made of plastic. The capacitive sensor 303 is configured with a capacitive sensor (such as a capacitor, a conductor, etc.) having a predetermined capacitance, and its capacitive component changes as a finger is brought closer to the surface on which the metallic paint 301 is coated. The finger is simulated with a conductor 305 made of a metal rod.

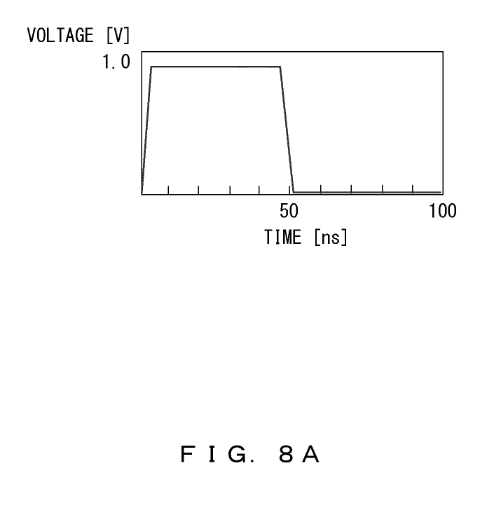

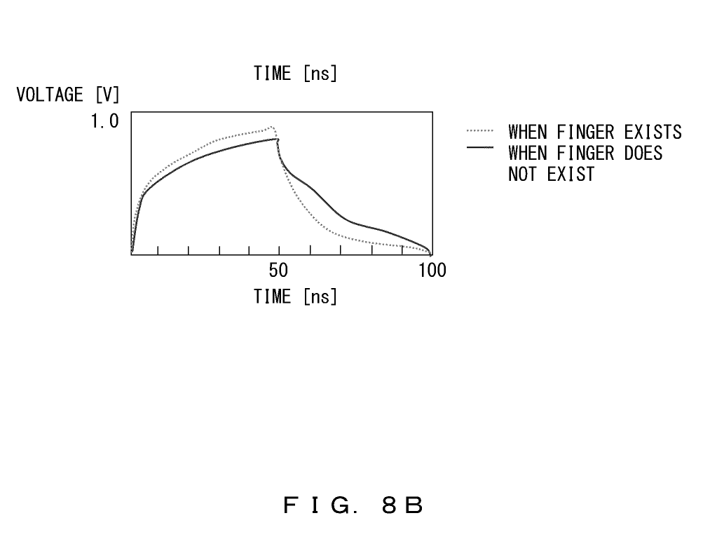

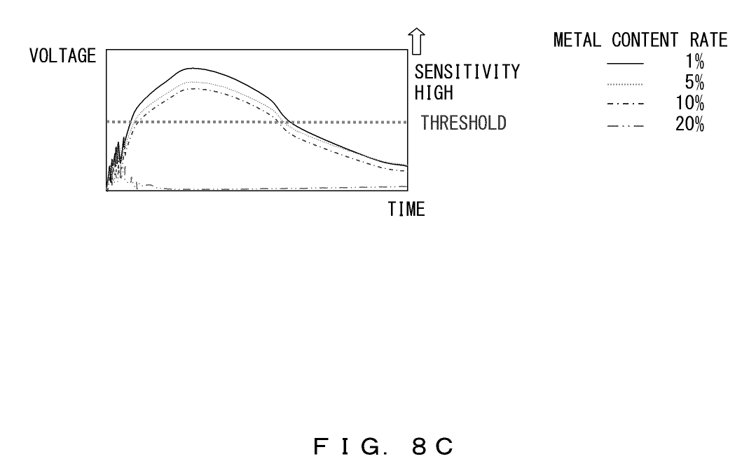

Here, when a predetermined input signal (for example, a signal indicated by FIG. 8A) is input from a wave source 306, the signal propagates through the capacitive sensor 303 and the ASIC 304, and is observed at an observation point 307. The waveform of the signal (hereinafter referred to as an observation signal) observed at the observation point 307 becomes moderate (for example, a signal indicated by FIG. 8B) with an internal resistance of the ASIC 304, etc., and the capacitor of the capacitive sensor 303.

Then, a differential signal between the input signal and the observation signal is obtained. If the differential signal becomes a predetermined threshold or larger, the finger (conductor 305) is determined to contact the surface on which the metallic paint 301 is coated.

Accordingly, with the electrical characteristic analysis process according to this preferred embodiment, whether or not the finger (conductor 305) can be detected to contact the surface on which the metallic paint 301 is coated can be determined depending on whether or not a difference of the predetermined threshold or larger exists by obtaining an observation signal with the analysis of an electric field E (and a magnetic field H) at the observation point 307 when a predetermined input signal is input to the wave source 306, and by making a comparison between the signals (for example, signals indicated by FIG. 8C) resultant from the analysis respectively in a case where the finger (conductor 305) contacts the surface on which the metallic paint 301 is coated (the conductor 305 exists), and in a case where the finger (conductor 305) does not contact the surface on which the metallic paint 301 is coated (the conductor 305 does not exist).

Consequently, whether or not the finger (conductor 305) can be detected to contact the surface on which the metallic paint 301 is coated can be determined at the rate of a metal content (hereinafter referred to simply as a metal content rate) of the metallic paint 301. Moreover, the range (or the upper limit value) of the metal content rate, which makes it possible to detect that the finger (conductor 305) contacts the surface on which the metallic paint 301 is coated, can be obtained by executing the electrical characteristic analysis process.

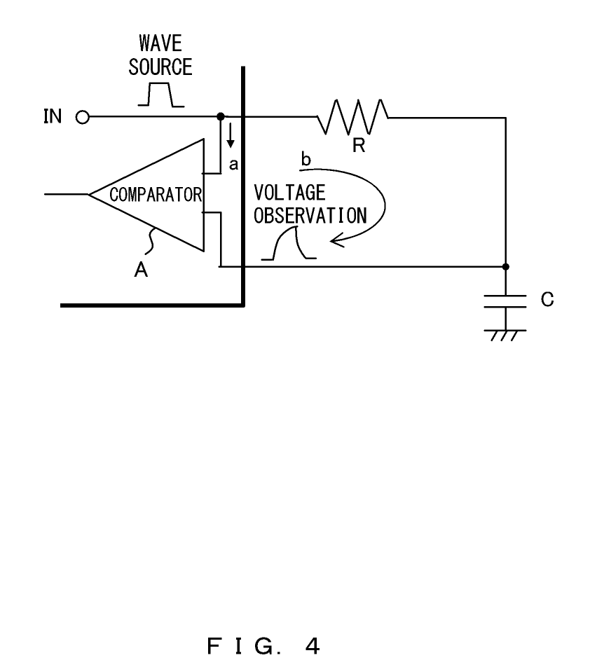

Here, the analysis model 300 shown in FIG. 3 can be considered as a circuit configuration shown in FIG. 4. Namely, this model can be considered as a lowpass filter circuit (hereinafter referred to simply as an RC circuit) configured with the internal resistance R of the ASIC 304, and the capacitor C of the capacitive sensor 303.

The RC circuit is connected to a comparator A not shown in FIG. 3. A differential signal which has a value of the predetermined threshold or larger is detected by making a comparison between a signal a (for example, the input signal indicated by FIG. 8A) provided to an input terminal IN, and a signal b obtained via the RC circuit.

For example, if the conductor 305 is brought close to the surface of the body, the capacitor C increases. Then, the signal b obtained via the RC circuit becomes moderate (is smoothed) as indicated by a solid line depicted in FIG. 8B. Therefore, a difference from the signal a increases. As a result, it can be determined that the conductor 305 contacts the surface of the body if a difference which has a value of the threshold or larger is detected.

If the values of the internal resistance R and the capacitor C are easily obtained, the signal b can be quantitatively calculated with the circuit shown in FIG. 4. This makes it possible to quantitatively obtain the range of a metal content rate, which can detect that the finger (conductor 305) contacts the surface on which the metallic paint 301 is coated.

Normally, however, it is difficult to calculate the capacitance of the capacitor C when the finger (conductor 305) is brought close to the surface on which the metallic paint 301 is coated. Therefore, the signal b obtained via the RC circuit when the conductor 305 is brought close to the surface on which the metallic paint 301 is coated is analytically calculated with an FDTD method, and the range of the metal content rate, which can detect that the finger (conductor 305) is brought close to the surface on which the metallic paint 301 is coated, is obtained.

As described above, the electrical characteristic analyzing apparatus 100 according to this preferred embodiment executes the electrical characteristic analysis process with an FDTD method. Accordingly, the analysis model 300 shown in FIG. 3 is partitioned into meshes of a predetermined size (Δx, Δy, Δz), and (vector magnitudes of) an electric field E and a magnetic field H in each of the meshes are obtained.

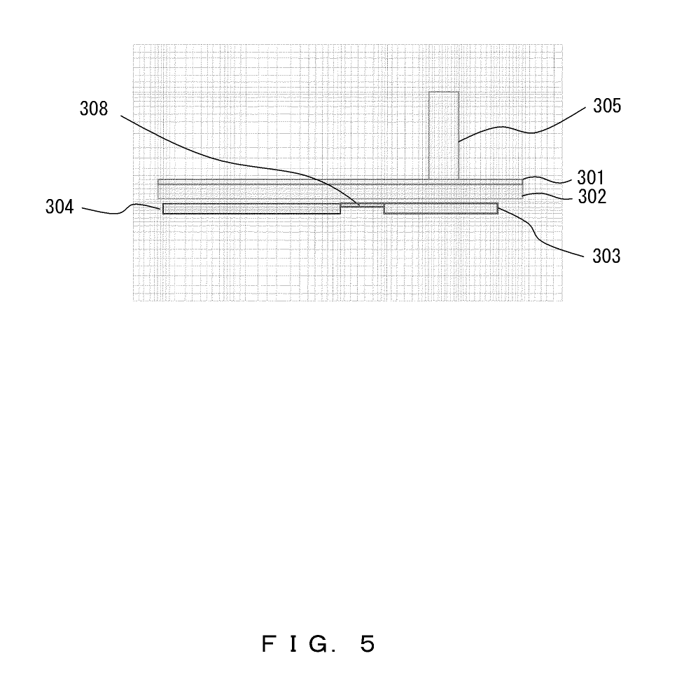

FIG. 5 is a cross-sectional view when the analysis model 300 according to this preferred embodiment is partitioned into meshes. With the electrical characteristic analysis process according to this preferred embodiment, the entire space within a predetermined range including the analysis model 300 is partitioned into meshes as indicated by dotted lines, and the electrical characteristic of the metallic paint 301 is obtained by analytically calculating the electric field E and the magnetic field H of this space.

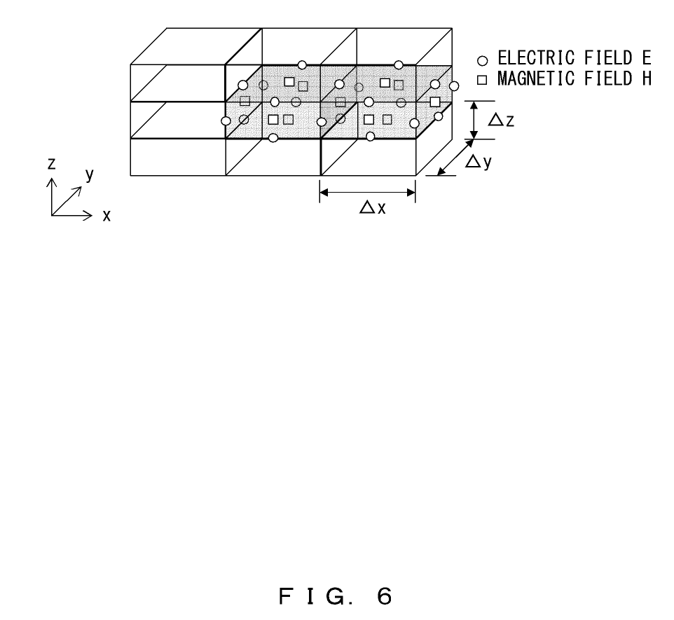

An enlarged view of partitioned meshes (Yee meshes) is shown in FIG. 6. Each of the meshes is a rectangular parallelpiped the width, the depth and the height of which are Δx, Δy, and Δz respectively. ∘ indicates an electric field E (a synthesized vector of electric fields Ex, Ey, and Ez) at a corresponding position, whereas □ indicates a magnetic field H (a synthesized vector of magnetic fields Hx, Hy, and Hz) at a corresponding position.

### Property Values

As property values of the metallic paint 301, the body 302, the capacitive sensor 303, the ASIC 304, and the conductor 305 according to this preferred embodiment, data of Table 1 is used.

| | PERMIT- | PERME- | CONDUC- |
|---|---|---|---|
| PROPERTY VALUE | TIVITY ε | ABILITY μ | TIVITY ρ [S/m] |
| METALLIC PAINT | 3.0 | 1.0 | (2.0) |
| BODY (PLASTIC) | 3.0 | 1.0 | 0.0 |
| CAPACITIVE SENSOR | — | — | 5.8e7 |
| ASIC (GROUND LAYER) | — | — | 5.8e7 |
| CONDUCTOR | 1.0 | 0.0 | 1.0e9 |

The conductivity ρ0 of the metallic paint 301 according to this preferred embodiment is calculated from a resistance value R0 that is measured beforehand. Assuming that the resistance value is R0 when the thickness of the metallic paint 301 is T and an area of the coated metallic paint 301 is S, the conductivity ρ0 can be obtained with the following equation.

ρ0=(1/R0)*(T/S) [S/m] (1)

### Electrical Characteristic Analysis Process

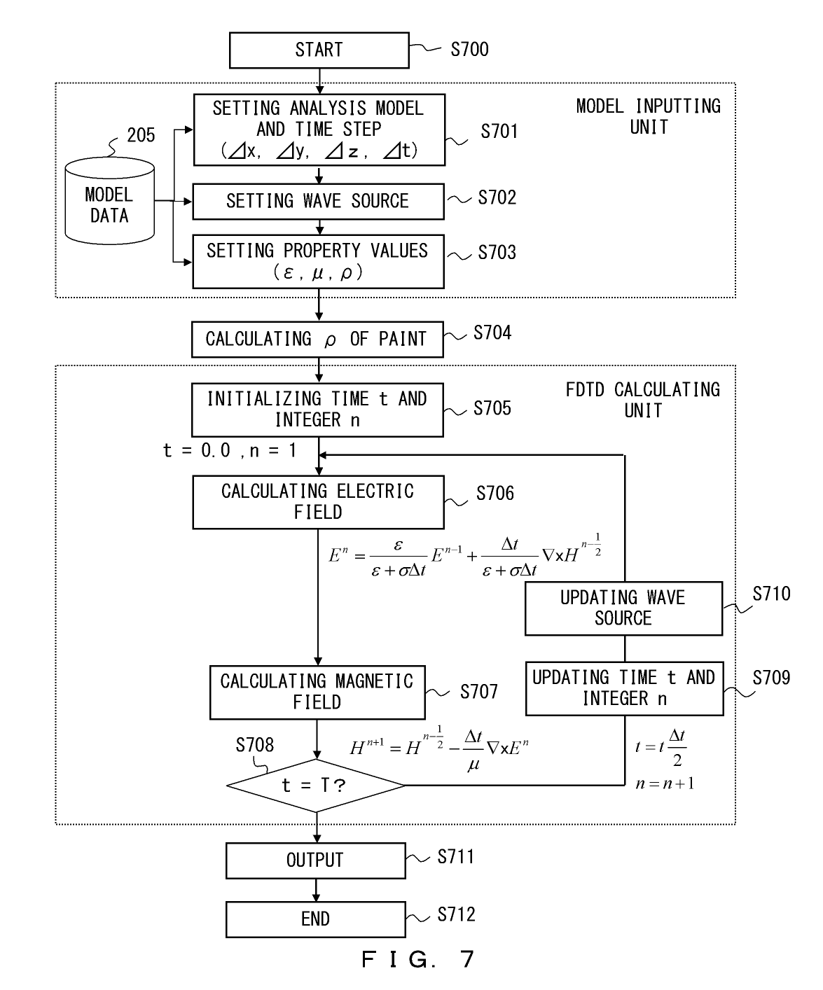

FIG. 7 is a flowchart showing a specific process of the electrical characteristic analyzing apparatus 100 according to this preferred embodiment.

A user inputs the shape, the wave source, the property values, etc. of the analysis model 300 shown in FIG. 3 to the external storage device 205 as model data. When the user performs a predetermined operation, the electrical characteristic analyzing apparatus 100 starts analyzing the electrical characteristic of the analysis model 300 (step S700).

In step S701, the electrical characteristic analyzing apparatus 100 refers to the external storage device 205 to read the shapes of the metallic paint 301, the body 302, the capacitive sensor 303, the ASIC 304 and the conductor 305, a partition width of mesh partitioning, and a time step (Δx, Δy, Δz, Δt).

In step S 702, the electrical characteristic analyzing apparatus 100 refers to the external storage device 205 to read the data of the wave source. In this preferred embodiment, the input signal indicated by FIG. 8A is used as the wave source.

In step S703, the electrical characteristic analyzing apparatus 100 refers to the external storage device 205 to read the property values (the permittivity ε, the permeability μ, and the conductivity ρ of other than the metallic paint 301) of the metallic paint 301, the body 302, the capacitive sensor 303, the ASIC 304 and the conductor 305, which are shown in Table 1.

Upon completion of the processes for reading and setting the analysis model 300 as described above, the electrical characteristic analyzing apparatus 100 moves the process to step S704.

In step S704, the electrical characteristic analyzing apparatus 100 calculates the conductivity ρ0 of the metallic paint 301. In this preferred embodiment, the resistance value R0 of the metallic paint 301 having the thickness T and the area S is actually measured, and stored in the external storage device 205 along with the information about the property values, etc. Then, the electrical characteristic analyzing apparatus 100 reads the thickness T, the area S and the resistance value R0, substitutes these values into the equation (1), and calculates the conductivity ρ0. The conductivity ρ0 that is calculated beforehand may be stored in the external storage device 205, and read along with the other property values in step S703.

After calculating the conductivity ρ0, the electrical characteristic analyzing apparatus 100 moves the process to step S705, and starts the electrical characteristic analysis process with an FDTD method. Since the technique for analyzing electric and magnetic fields with an FDTD method is a known technique, its detailed explanation is omitted here.

In step S705, the electrical characteristic analyzing apparatus 100 initializes a time t and an integer n to 0 and 1 respectively. Then, the electrical characteristic analyzing apparatus 100 moves the process to step S706.

In step S706, the electrical characteristic analyzing apparatus 100 calculates the electric field E. Here, the electric field E can be obtained by providing the permittivity ε, the conductivity ρ, and the time step At to the following equation. As the permittivity ε and the conductivity ρ, a permittivity and a conductivity according to the material (the metallic paint, plastic, the capacitive sensor, the conductor, etc.) at a corresponding position (x,y,z) are selected, and substituted into the equation (2).

$${E}^{n} = \frac{σ}{ɛ + σ • t} {E}^{n - 1} + \frac{• t}{ɛ + σ • t} ∇ \times {H}^{n - \frac{1}{2}} \qquad ( 2 )$$

Upon completion of the calculation of the electric field E, the electrical characteristic analyzing apparatus 100 moves the process to step S707 after executing an absorbing boundary process such as an impedance matching, etc. as needed.

Instep S707, the electrical characteristic analyzing apparatus 100 calculates the magnetic field H. Here, the magnetic field H can be obtained by providing the permeability μ and the time step Δ to the following equation. Also as the permeability μ, a permeability according to the material at a corresponding position (x,y,z) is selected, and substituted into the equation (3).

$${H}^{n + 1} = {H}^{n - \frac{1}{2}} - \frac{Δ t}{μ} ∇ \times {E}^{n} \qquad ( 3 )$$

Upon completion of the calculation of the magnetic field H, the electrical characteristic analyzing apparatus 100 moves the process to step S708 to check whether or not the time t matches a predetermined time T. If the time t does not match the predetermined time T, the electrical characteristic analyzing apparatus 100 moves the process to step S709.

In step S709, the electrical characteristic analyzing apparatus 10 updates the time t and the integer n. Since the time step is assumed to be At in this preferred embodiment, t+(Δt/2) is substituted into the time t. Additionally, the integer n is incremented by 1.

After updating the time t and the integer n, the electrical characteristic analyzing apparatus 100 moves the process to step S710. Then, the electrical characteristic analyzing apparatus 100 updates the wave source. Namely, the electrical characteristic analyzing apparatus 100 obtains the electric field E of the wave source at the updated time t. Then, the electrical characteristic analyzing apparatus 100 returns the process to step S706.

As described above, the electrical characteristic analyzing apparatus 100 obtains the electric field E, namely, a potential V at an observation point by executing the processes of steps S706 to S710 until the time t reaches the predetermined time T.

If the time t matches the predetermined time T in step S708, the electrical characteristic analyzing apparatus 100 moves the process to step S711. Then, the electrical characteristic analyzing apparatus 100 outputs the potential V obtained with the processes of steps S706 to S710 to the external storage device 205 to store the potential V. Then, the electrical characteristic analyzing apparatus 100 moves the process to step S712, and terminates the electrical characteristic analysis process.

The above provided explanation of the preferred embodiment refers to the case where the signal indicated by FIG. 8A is provided at the wave source. However, by way of example, also for a case where an electromagnetic signal is provided at an arbitrary position, an electrical characteristic at an observation point can be analytically calculated with similar procedures.

FIGS. 8A, 8B, and 8C are waveform diagrams showing signals at the wave source 306 and the observation point 307 of the analysis model 300 according to this preferred embodiment.

FIG. 8A represents the input signal to the wave source 306 according to this preferred embodiment. FIG. 8B represents electrical characteristics at the observation point 307, which are obtained with the electrical characteristic analysis process according to this preferred embodiment. A solid line represents a characteristic when the finger (conductor 305) contacts the surface on which the metallic paint 301 is coated, whereas a dotted line represents a characteristic when the finger does not contact the surface on which the metallic paint 301 is coated.

FIG. 8C is a graph representing differences between results of the electrical characteristic analysis when the finger (conductor 305) contacts the surface on which the metallic paint 301 is coated, and those when the finger (conductor 305) does not contact the surface on which the metallic paint 301 is coated in cases where the metal content rate of the metallic paint 301 is 1 percent (solid line), 5 percent (dotted line), 10 percent (one-dot-dashed line), and 20 percent (two-dot-dashed line).

It is proved from the graph of FIG. 8C that a response to the input signal of FIG. 8A is dropped to a predetermined threshold or smaller when the metal content rate is 20 percent. Accordingly, it can be determined that the upper limit of the metal content rate of the metallic paint 301 is approximately 10 percent.

As described above, the electrical characteristic analyzing apparatus 100 according to this preferred embodiment calculates the permeability ρ0 of the metallic paint 301 from the resistance value R0 of the metallic paint 301, which is measured beforehand, and calculates the electric field E and the magnetic field H of the metallic paint 301 by regarding the paint as a dielectric having a predetermined conductivity.

Therefore, a special analysis model for the metallic paint 301 is not required. Accordingly, the electric field E and the magnetic field H at an observation point according to an (electric or magnetic) signal provided from a predetermined wave source can be analytically calculated with ease for a substance on which the metallic paint 301 is coated. Additionally, since a special analysis model is not required, for example, a calculation time can be reduced.

What is claimed is:

1. An electrical characteristic analyzing apparatus for analyzing an electrical characteristic at an observation point according to an electric or magnetic signal, which is provided from a wave source, for a substance on which a paint containing a metal at a predetermined ratio is coated, comprising:
an analysis model obtaining unit for reading from a storing unit analysis model information that defines a domain to be analyzed, which includes the substance on which the paint is coated;
a wave source information obtaining unit for reading from the storing unit signal information provided from the wave source;
a property value obtaining unit for reading from the storing unit property values of the substance within the domain to be analyzed, which include a conductivity of the paint; and
an electromagnetic field analyzing unit for obtaining a change in electric and magnetic fields at the observation point according to the electric or magnetic signal provided from the wave source by analytically calculating electric and magnetic fields of each of meshes, into which the domain to be analyzed is partitioned, based on Maxwell's equations.

2. The electrical characteristic analyzing apparatus according to claim 1, wherein
the analysis model information includes at least shapes of the paint and the substance, the domain to be analyzed, which includes the substance on which the paint is coated, a size of the meshes into which the domain is partitioned, and a time step that is a minimum unit of an analysis time.

3. The electrical characteristic analyzing apparatus according to claim 1, further comprising
a conductivity calculating unit for calculating a conductivity of the paint from a resistance value of the paint, which is measured beforehand, and for storing the calculated conductivity in the storing unit.

4. The electrical characteristic analyzing apparatus according to claim 1, wherein
said electromagnetic field analyzing unit analytically calculates the paint as a dielectric having a conductivity.

5. The electrical characteristic analyzing apparatus according to claim 1, wherein
said electromagnetic field analyzing unit performs calculation based on an FDTD (Finite Difference Time Domain) method.

6. An electrical characteristic analyzing method for analyzing an electrical characteristic at an observation point according to an electric or magnetic signal, which is provided from a wave source, for a substance on which a paint containing a metal at a predetermined ratio is coated, comprising:
an analysis model obtaining process of reading analysis model information from an analysis model information storing unit for storing the analysis model information that defines a domain to be analyzed, which includes the substance on which the paint is coated;
a wave source information obtaining process of reading signal information from a signal information storing unit for storing the signal information provided from the wave source;
a property value obtaining process of reading property values from a property value storing unit for storing the property values of the substance within the domain to be analyzed, which include a conductivity of the paint; and
an electromagnetic field analyzing process of obtaining a change in electric and magnetic fields at the observation point according to the electric or magnetic signal provided from the wave source by analytically calculating electric and magnetic fields of each of meshes, into which the domain to be analyzed is partitioned, based on Maxwell's equations.

7. The electrical characteristic analyzing method according to claim 6, wherein
the analysis model information includes at least shapes of the paint and the substance, the domain to be analyzed, which includes the substance on which the paint is coated, a size of the meshes into which the domain is partitioned, and a time step that is a minimum unit of an analysis time.

8. The electrical characteristic analyzing method according to claim 6, further comprising
a conductivity calculating process of calculating a conductivity of the paint from a resistance value of the paint, which is measured beforehand, and of storing the calculated conductivity in the storing unit.

9 . The electrical characteristic analyzing method according to claim 6, wherein
said electromagnetic field analyzing process analytically calculates the paint as a dielectric having a conductivity.

10. The electrical characteristic analyzing method according to claim 6, wherein
said electromagnetic field analyzing process performs calculation based on an FDTD (Finite Difference Time Domain) method.

11. A program for causing an information processing device to execute an electrical characteristic analysis process for analyzing an electrical characteristic at an observation point according to an electric or magnetic signal, which is provided from a wave source, for a substance on which a paint containing a metal at a predetermined ratio is coated, the process comprising:
an analysis model obtaining process for reading analysis model information from an analysis model information storing unit for storing the analysis model information that defines a domain to be analyzed, which includes the substance on which the paint is coated;
a wave source information obtaining process for reading signal information from a signal information storing unit for storing the signal information provided from the wave source;
a property value obtaining process for reading property values from a property value storing unit for storing the property values of the substance within the domain to be analyzed, which include a conductivity of the paint; and
an electromagnetic field analyzing process for obtaining a change in electric and magnetic fields at the observation point according to the electric or magnetic signal provided from the wave source by analytically calculating electric and magnetic fields of each of meshes, into which the domain to be analyzed is partitioned, based on Maxwell's equations.

12. The recording medium according to claim 11, wherein
the analysis model information includes at least shapes of the paint and the substance, the domain to be analyzed, which includes the substance on which the paint is coated, a size of the meshes into which the domain is partitioned, and a time step that is a minimum unit of an analysis time.

13. The recording medium according to claim 11, the process further comprising
a conductivity calculating process for calculating a conductivity of the paint from a resistance value of the paint, which is measured beforehand, and for storing the calculated conductivity in the storing unit.

14. The recording medium according to claim 11, wherein
said electromagnetic field analyzing process analytically calculates the paint as a dielectric having a conductivity.

15. The recording medium according to claim 11, wherein
said electromagnetic field analyzing process performs calculation based on an FDTD (Finite Difference Time Domain) method.
